(19) United States
(12) Patent Application Publication
(10) Pub. No.: US 2014/0158966 A1
(43) Pub. Date: Jun. 12, 2014

(54) VARIABLE RESISTANCE MEMORY DEVICE AND METHOD FOR FABRICATING THE SAME

(71) Applicant: SK HYNIX INC., Icheon (KR)

(72) Inventor: Wan-Gee KIM, Icheon (KR)

(73) Assignee: SK HYNIX INC., Icheon (KR)

(21) Appl. No.: 13/846,502

(22) Filed: Mar. 18, 2013

(30) Foreign Application Priority Data
Dec. 7, 2012 (KR) 10-2012-0141948

(51) Int. Cl. H01L 45/00

(52) U.S. Cl. CPC H01L 45/1253; H01L 45/16
USPC 257/4; 438/382

(57) ABSTRACT

A method for fabricating a variable resistance memory device includes: forming a first metal oxide layer over a first electrode; performing a first implantation process using a first element to a first depth of the first metal oxide layer so as to reduce at least a portion of the first metal oxide layer and form a first oxygen-deficient metal oxide layer; forming a second electrode over the first metal oxide layer; forming a second metal oxide layer over the second electrode; performing a second implantation process using a second element to a second depth of the second metal oxide layer so as to reduce at least a portion of the second metal oxide layer and form a second oxygen-deficient metal oxide layer; and forming a third electrode over the second metal oxide layer.

### CROSS-REFERENCE TO RELATED APPLICATIONS

The present application claims priority of Korean Patent Application No. 10-2012-0141948, filed on Dec. 7, 2012, which is incorporated herein by reference in its entirety.

### BACKGROUND

1. Field

Exemplary embodiments relate to a semiconductor technology, and more particularly, to a variable resistance memory device and a method for fabricating the same.

2. Description of the Related Art

Recently, a variety of variable resistance memory devices have been developed. The variable resistance memory device refers to a device which stores data using a variable resistance material switching between different resistance states depending on an applied bias.

Among the variety of variable resistance memory devices is a variable resistance memory device which performs a switching operation by locally generating or dissipating a filament serving as a current path in a variable resistance material layer formed (e.g. of metal oxide), is referred to as ReRAM (Resistive Random Access Memory). Since the creation/dissipation of the filament occurs according to a change in amount of oxygen vacancies in the metal oxide, the variable resistance material layer comprises a layer including oxygen vacancies.

Specifically, the variable resistance material layer may include: a double layer of (i) an oxygen-deficient metal oxide layer containing oxygen at a lower ratio than a stoichiometric ratio and thus including a large quantity of oxygen vacancies; and (ii) an oxygen-rich metal oxide layer satisfying the stoichiometric ratio. The oxygen-deficient metal oxide layer serves to supply oxygen vacancies to the oxygen-rich metal oxide layer. The oxygen-rich metal oxide layer serves as a layer in which a filament is created or dissipated, depending on whether oxygen vacancies are introduced from the oxygen-deficient metal oxide layer, and switching actually occurs.

However, when the above-described double layer is formed, various problems may occur.

For example, when each of the oxygen-deficient metal oxide layer and the oxygen-rich metal oxide layer is formed by a deposition method, an unintended resistance is caused between the oxygen-deficient metal oxide layer and the oxygen-rich metal oxide layer. The unintended resistance may interfere with a movement of oxygen during a switching operation. As a result, a normal switching operation may be adversely affected.

Furthermore, when a metal oxide is used, the oxygen-deficient metal oxide layer may be formed at a bottom level, and the oxygen-rich metal oxide layer may be formed at a top level. As the oxygen-rich metal oxide layer is deposited, the oxygen-deficient metal oxide layer at the bottom may be subject to oxidation or damaged by plasma. In this case, the oxygen vacancy amount (or density) of the oxygen deficient metal oxide layer may be changed. As a result, a desired switching operation may be hindered.

### SUMMARY

Various embodiments are directed to a variable resistance memory device and a method for fabricating the same, which is capable of implementing a multi-stack structure which has an excellent switching characteristic through process improvement and form symmetry.

In an embodiment, a method for fabricating a variable resistance memory device includes: forming a first metal oxide layer over a first electrode; performing a first implantation process using a first element to a first depth of the first metal oxide layer so as to reduce at least a portion of the first metal oxide layer and form a first oxygen-deficient metal oxide layer; forming a second electrode over the first metal oxide layer; forming a second metal oxide layer over the second electrode; performing a second implantation process using a second element to a second depth of the second metal oxide layer so as to reduce at least a portion of the second metal oxide layer and form a second oxygen-deficient metal oxide layer; and forming a third electrode over the second metal oxide layer.

In another embodiment, a method for fabricating a variable resistance memory device includes: forming a first metal oxide layer over a first electrode; performing a first implantation process using a first element to a first depth of the first metal oxide layer so as to oxidize at least a portion of the first metal oxide layer and form a first oxygen-rich metal oxide layer; forming a second electrode over the first metal oxide layer; performing a second implantation process using a second element to a second depth of the second metal oxide layer so as to oxidize at least a portion of the second metal oxide layer and form a second oxygen-rich metal oxide layer; and forming a third electrode over the second metal oxide layer.

In another embodiment, a variable resistance memory device includes: a first electrode; a first variable resistance material layer formed over the first electrode and comprising a stack of a first oxygen-deficient metal oxide layer and a first oxygen-rich metal oxide layer; a second electrode over the first variable resistance material layer; a second variable resistance material layer formed over the second electrode and comprising a stack of a second oxygen-deficient metal oxide layer and a second oxygen-rich metal oxide layer; and a third electrode over the second variable resistance material layer, wherein the first and the second variable resistance material layers in a symmetrical configuration with respect to the second electrode interposed therebetween, and wherein, in each of the first and the second oxygen-deficient metal oxide layers, an oxygen-per-metal ratio is the lowest at a given level and increases as a distance from the given level increases in a thickness direction.

In another embodiment, a variable resistance memory device includes: a first electrode; a first variable resistance material layer formed over the first electrode and comprising a stock of a first oxygen-deficient metal oxide layer and a first oxygen-rich metal oxide layer; a second electrode over the first variable resistance material layer; a second variable resistance material layer formed over the second electrode and comprising a stack of a second oxygen-deficient metal oxide layer and a second oxygen-rich metal oxide layer; and a third electrode over the second variable resistance material layer, wherein the first and second variable resistance material layers are in a symmetrical configuration with respect to the second electrode interposed therebetween, and wherein, in each of the first and the second oxygen-rich metal oxide layers, an oxygen-per-metal ratio is the highest at a given level and decreases as a distance from the given level increases in a thickness direction.

In another embodiment, a method for fabricating a variable resistance memory device includes: providing a first metal oxide layer over a first electrode, wherein the first metal oxide layer has a first oxygen-per-metal ratio; performing a first implantation process to the first metal oxide layer to modify a portion of the first metal oxide layer into a first modified metal oxide layer, wherein the first modified metal oxide layer has a second oxygen-per-metal ratio different from the first oxygen-per-metal ratio; forming a second electrode over a stack of the first metal oxide layer and the first modified metal oxide layer; forming a second metal oxide layer over the second electrode, wherein the second metal oxide layer has a third oxygen-per-metal ratio; performing a second implantation process to the second metal oxide layer to modify a portion of the second metal oxide layer into a second modified metal oxide layer, wherein the second modified metal oxide layer has a fourth oxygen-per-metal ratio different from the third oxygen-per-metal ratio.

In another embodiment, a variable resistance memory device includes: a first electrode; a first variable resistance material layer formed over the first electrode and comprising a stack of a first oxygen-deficient metal oxide layer and a first oxygen-rich metal oxide layer; a second electrode over the first variable resistance material layer; a second variable resistance material layer formed over the second electrode and comprising a stack of a second oxygen-deficient metal oxide layer and a second oxygen-rich metal oxide layer; and a third electrode over the second variable resistance material layer, wherein when each the first and the second oxygen-deficient metal oxide layers is configured to have a differential oxygen-per-metal ratio profile along a thickness direction, each of the first and the second oxygen-rich metal oxide layers is configured to have a substantially uniform oxygen-per-metal ratio profile along the thickness direction, and wherein when each the first and the second oxygen-deficient metal oxide layers is configured to have a substantially uniform oxygen-per-metal ratio profile along the thickness direction, each of the first and the second oxygen-rich metal oxide layers is configured to have a differential oxygen-per-metal ratio profile along the thickness direction.

### BRIEF DESCRIPTION OF THE DRAWINGS

FIGS. 1A to 1F are cross-sectional views illustrating a variable resistance memory device and a method for fabricating the same in accordance with an embodiment.

FIG. 2 is a cross-sectional view for explaining an oxygen concentration gradient of an oxygen-deficient metal oxide layer of FIGS. 1A to 1F.

FIG. 3 is a cross-sectional view illustrating a variable resistance memory device and a method for fabricating the same in accordance with another embodiment.

FIG. 4 is a cross-sectional view illustrating a variable resistance memory device in accordance with another embodiment.

FIG. 5 is a perspective view of a variable resistance memory device in accordance with another embodiment.

FIGS. 6A to 6D are cross-sectional views illustrating a variable resistance memory device and a method for fabricating the same in accordance with another embodiment.

FIG. 7 is a cross-sectional view for explaining the oxygen concentration gradient of an oxygen-rich metal oxide layer of FIGS. 6A to 6D.

### DETAILED DESCRIPTION

Various embodiments will be described below in more detail with reference to the accompanying drawings. Embodiments may, however, take different forms and should not be construed as limited to those set forth herein. Throughout the disclosure, like reference numerals refer to like parts throughout the various figures and embodiments.

The drawings are not necessarily to scale, and in some instances proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

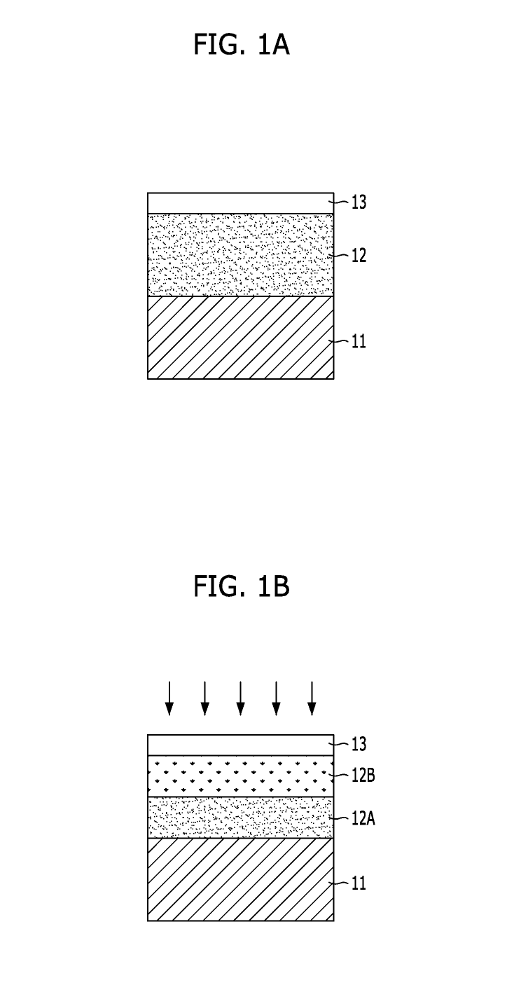

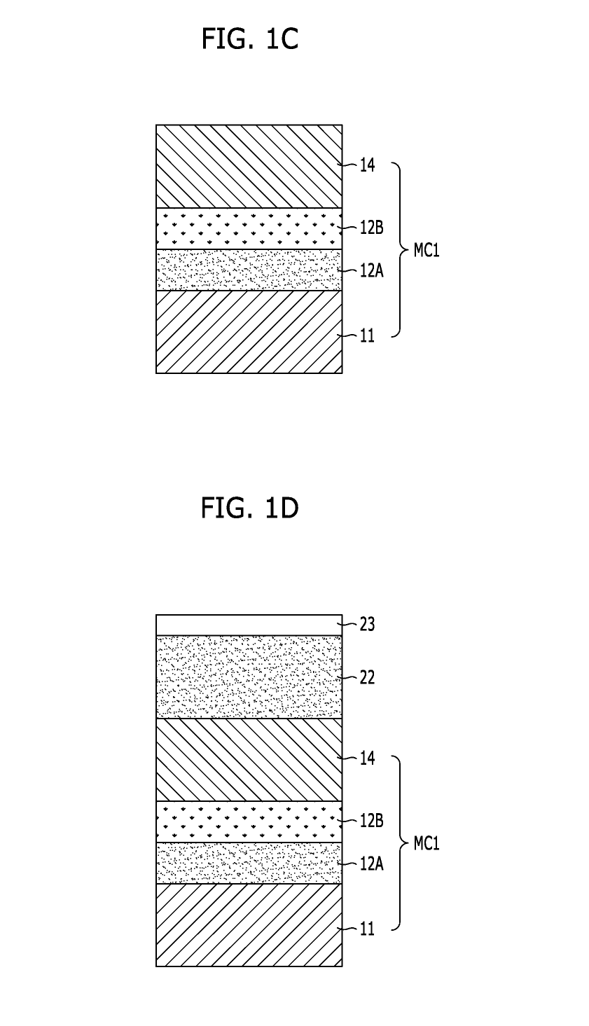

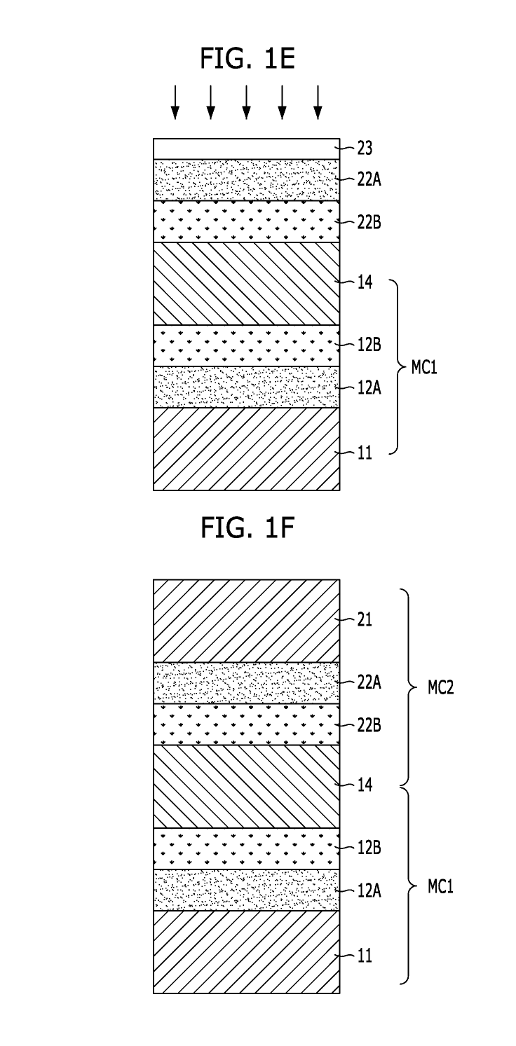

FIGS. 1A to 1F are cross-sectional views illustrating a variable resistance memory device and a method for fabricating the same in accordance with an embodiment. In particular, FIG. 1F illustrates a structure in which two unit memory cells are sequentially stacked, and FIGS. 1A to 1E illustrate process steps for fabricating the structure shown in FIG. 1F.

Referring to FIG. 1A, a first electrode 11 is formed over a substrate (not illustrated) including a predetermined lower structure. The first electrode 11 serves to apply a voltage to a variable resistance material layer and will be described in detail below. The first electrode 11 may include conductive materials, for example, metals such as platinum (Pt), tungsten (W), aluminum (Al), copper (Cu), tantalum (Ta) and the like or metal nitrides such as titanium nitride (TiN), tantalum nitride (TaN) and the like.

The first metal oxide layer 12 is formed over the first electrode 11. The first metal oxide layer 12 may include Ti oxide, Ta oxide, Fe oxide, W oxide, Hf oxide, Nb oxide, Zr oxide and the like. Furthermore, the first metal oxide layer 12 may include an oxygen-rich metal oxide layer having a relatively high oxygen-per-metal ratio, compared with an oxygen-deficient metal oxide layer. For example, the first metal oxide layer 12 may include a metal oxide layer such as TiO₂ or Ta₂O₅, which satisfies a stoichiometric ratio.

Then, a first passivation layer 13 is formed over the first metal oxide layer 12. The first passivation layer 13 may serve to prevent the first metal oxide layer 12 and the first electrode 11 from being damaged during a subsequent implant process, and may be formed of an insulator including oxide such as SiO₂ and nitride such as SiN.

Referring to FIG. 1B, implantation using an element capable of reducing oxygen-per-metal ratio is performed to the first metal oxide layer 12 along the arrows, and a heat treatment is performed to reduce a portion of the first metal oxide layer 12. For convenience of description, the implantation to the first metal oxide layer 12 is referred to as a primary implant. The reduced portion of the first metal oxide layer 12 which is subject to the primary implantation has a lower oxygen-per-metal ratio than that of the remaining portion the first metal oxide layer 12 which is not subject to the primary implantation. Hereafter, the portion which is subject to the primary implantation is referred to as a first oxygen-deficient metal oxide layer 12B. Furthermore, the remaining portion of the first metal oxide layer 12 which is not subject to the primary implantation is referred to as a first oxygen-rich metal oxide layer 12A. As described above, the first oxygen-rich metal oxide layer 12A indicates a layer having a higher oxygen-per-metal ratio than that of the first oxygen-deficient metal oxide layer 12B. For example, the first oxygen-rich metal oxide layer 12A may be a layer which satisfies a stoichiometric ratio, and the first oxygen-deficient metal oxide layer 12B may be a layer which contains oxygen at a lower ratio than the stoichiometric ratio. For example, when the first oxygen-rich metal oxide layer 12A includes Ta₂O₅, the first oxygen-deficient metal oxide layer 12B may include TaOx (here, 0≦x≦2.5), or when the first oxide-rich metal oxide layer 12B include TiO₂, the first oxygen-deficient metal oxide layer 12B may include TiOx (here, 0≦x≦2). However, embodiments are not limited thereto.

Energy of the implantation process may be adjusted to control a target depth. Thus, the first oxygen-deficient metal oxide layer 12B may be formed at a desired position.

In this embodiment, as relatively low energy is used to perform the primary implant, the top portion of the first metal oxide layer 12 is reduced to the first oxygen-rich metal oxide layer 12B. However, embodiments are not limited thereto. The oxygen-rich metal oxide layer may be formed at a different position rather than the top portion by adjusting implantation energy of the implant process. Accordingly, the oxygen-rich metal oxide layer may be formed at a desired position in the first metal oxide layer 12.

Furthermore, the element used to change the oxygen-per-metal ratio may include hydrogen (H), for example. The implant process may include an ion implant process using H-containing gas (for example, H₂ gas, NH₃ gas or the like) as an ion source gas. However embodiments are not limited thereto and various elements capable of reducing the first metal oxide layer 12 (such as silicon (Si) or aluminum (Al)) may be used during the implant process.

Referring to FIG. 1C, the first passivation layer 13 is removed, and a second electrode 14 is formed over the resultant structure. The second electrode 14 may include conductive materials, including but not limited to metals such as Pt, W, Al, Cu, and Ta, and/or metal nitrides such as TiN and TaN.

Accordingly a first memory cell MC1 has a first variable resistance material layer, and the first and second electrodes 11 and 14. The first variable resistance material layer is interposed between the first and second electrodes 11 and 14. The first variable resistance material layer comprises the first oxygen-rich metal oxide layer 12A and the first oxygen-deficient metal oxide layer 12B.

Referring to FIG. 1D, a second metal oxide layer 22 is formed over the second electrode 14. The second metal oxide layer 22 may be formed of the same material as the first metal oxide layer 12, and may be formed to the same thickness as the first metal oxide layer 12. Accordingly, the second metal oxide layer 22 may include an oxygen-rich metal oxide layer having a relatively high oxygen-per-metal ratio. For example, the first metal oxide layer 22 may include metal oxide such as TiO₂ or Ta₂O₅, which satisfies a stoichiometric ratio.

Then, a second passivation layer 23 is formed over the second metal oxide layer 22. The second passivation layer 23 may serve to prevent the second metal oxide layer 22 and the second electrode 14 from being damaged during a subsequent implant process.

Referring to FIG. 1E, as shown by the arrows an element is implanted into the second metal oxide layer 22, and a heat treatment is performed to reduce a portion of the second metal oxide layer 22 into a second oxygen-deficient metal oxide layer 22B. The remaining portion of the second metal oxide layer 22 (which is not reduced into the second oxygen-deficient metal oxide layer 22B), is referred to as a second oxygen-rich metal oxide layer 22A. For convenience of description, the implantation made into the second metal oxide layer 22 is referred to as a secondary implantation.

In this embodiment, higher energy than that used during the first implantation is used to perform the second implantation. Accordingly, a bottom part of the second metal oxide layer 22 may be reduced into the second oxygen-deficient metal oxide layer 22B. Other than the implantation energy, in some embodiments, the second implantation may be performed under the same conditions as the first implantation.

Referring to FIG. 1F, the second passivation layer 23 is removed, and a third electrode 21 is formed over the resultant structure. The third electrode 21 may include conductive materials, for example metals such as Pt, W, Al, Cu, and Ta, and/or metal nitrides such as TiN and TaN.

As a result, a second memory cell MC2 has a second variable resistance material layer, and the second and third electrodes 14 and 21. The second variable resistance material layer is formed between the second and third electrodes 14 and 21. The second variable resistance material layer includes the second oxygen-deficient metal oxide layer 22B and the second oxygen-rich metal oxide layer 22A.

As a result, referring to FIG. 1F, a stacked structure of the first and second memory cells MC1 and MC2 may be fabricated. The first and second memory cells MC1 and MC2 share the second electrode 14, and the first variable resistance material layer 12A and 12B and the second variable resistance material layer 22A and 22B are formed to be symmetrical with each other, with respect to the second electrode 14A. That is, in the first memory cell MC1 the first oxygen-rich metal oxide layer 12A may be disposed at the top, and the first oxygen-deficient metal oxide layer 12B may be disposed at the bottom. In the second memory cell MC2, however, the second oxygen-deficient metal oxide layer 22B may be disposed at the bottom and the second oxygen-rich metal oxide layer 22A may be disposed at the top.

The variable resistance memory device and the method for fabricating the same in accordance with the embodiment may offer one or more benefits.

First, when the variable resistance material layer including a double layer of an oxygen-deficient metal oxide layer and an oxygen-rich metal oxide layer is formed, a deposition process can be obviated.

That is, a deposition process for forming the oxygen-deficient metal oxide layer can be replaced with an implantation process. Therefore, since an interface due to different depositions is not formed between the oxygen-rich metal oxide layer 12A or 22A and the oxygen-deficient metal oxide layer 12B or 22B, it is possible to prevent problems caused by the presence of the interface. Moreover, a fabrication process may be simplified, and the cost may be reduced.

Furthermore, since a target depth of the implantation may be controlled by varying implantation energy, the oxygen-deficient metal oxide layer may be easily formed at a desired position.

In addition, the structure in which the oxygen-deficient metal oxide layer is formed under the oxygen-rich metal oxide layer, may be easily implemented. In accordance with the embodiment, the position of the oxygen-deficient metal oxide layer may be easily controlled by adjusting the implant energy. Therefore, the structure in which two memory cells are stacked symmetrically with each other, may be easily created.

Although not illustrated, a structure in which three or more memory cells are stacked symmetrically with each other, may also be easily created. For example a structure including the same components as the first variable resistance material layer 12A and 12B and the second electrode 14, may be stacked over the second memory cell MC, thereby forming a third memory cell (not illustrated) sharing the third electrode 21 with the second memory cell MC.

Furthermore, a structure including the components corresponding to the second variable resistance material layer 22A and 22B and the third electrode 21 may be stacked over the third memory cell, thereby forming a fourth memory cell sharing one electrode with the third memory cell. That is, three or more memory cells may be stacked while sharing one electrode. A variable resistance material layer of each memory cell may be symmetrical to a variable resistance material layer of another memory cell.

Furthermore, when the first oxygen-deficient metal oxide layer 12B may be located below the first oxygen-rich metal oxide layer 12A in the first memory cell MC1, such a symmetrical structure may be implemented by using a relatively higher implantation energy (compared to that used in the process for forming the first memory cell MC1) in the process for forming the second memory cell MC2. As such, when the stacking order of the first oxygen-deficient metal oxide layer 12B and the first oxygen-rich metal oxide layer 12A of the first memory cell MC1 is exchanged, the stacking order of the second oxygen-rich metal oxide layer 22A and the second oxygen-deficient metal oxide layer 22B of the second memory cell MC2 may be exchanged as well, so that a symmetrical structure to the first memory cell MC1 can be obtained. In that case, symmetrical structure may be implemented by using lower implantation energy in the process for forming the first memory cell MC1 compared to the implantation energy employed for forming the first oxygen-deficient metal oxide layer 12B.

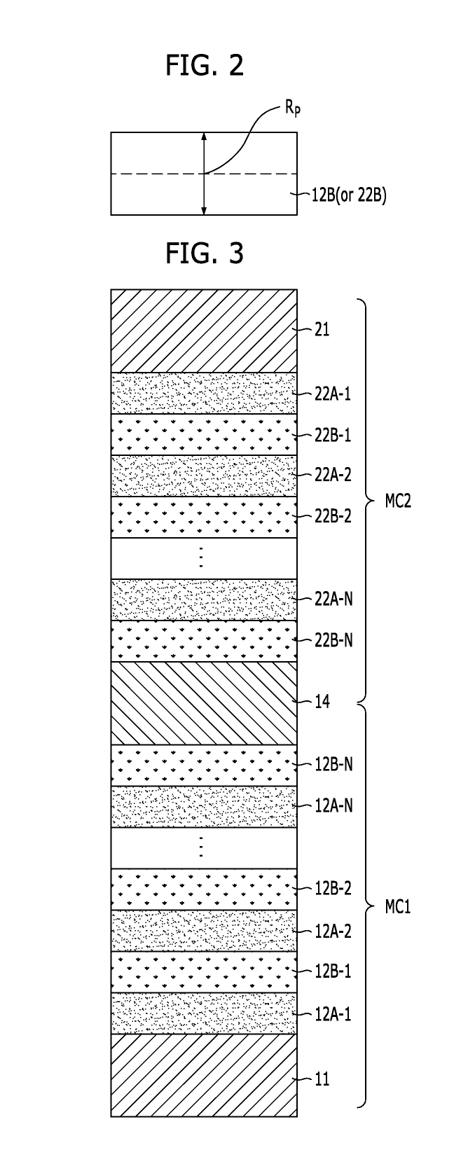

FIG. 2 is a cross-sectional view for explaining an oxygen concentration gradient of the oxygen-deficient metal oxide layer shown in FIGS. 1A to 1F.

As described above, the first oxygen-deficient metal oxide layer 12B may be formed by an implantation and heat treatment. A certain range of depth where the element is implanted, is referred to as a projected range (Rp). During the heat treatment after the implantation, the element is diffused in a vertical direction from the Rp (refer to a dotted line). As a result, the first oxygen-deficient metal oxide layer 12B is formed.

Therefore, referring to FIG. 2, the first oxygen-deficient metal oxide layer 12B may have an oxygen concentration profile. The oxygen concentration is the lowest at the Rp and increases along the vertical direction extending from the Rp. The vertical direction is shown as arrows.

Similarly, the second oxygen-deficient metal oxide layer 22B may have an oxygen concentration profile in which the oxygen concentration is the lowest at the Rp and increases along the vertical direction extending from the Rp (the direction of the arrows).

FIG. 3 is a cross-sectional view illustrating a variable resistance memory device and a method for fabricating the same in accordance with another embodiment. The following descriptions will be focused on differences from the above-described embodiment of FIGS. 1A to 1F.

Referring to FIG. 3, a first metal oxide layer 12 of FIG. 1A is formed over a first electrode 11, and a primary implantation process for reducing a portion of the first metal oxide layer is performed with having a passivation layer (not illustrated) over the first metal oxide layer.

At this time, a plurality of implantations may be performed at different energies so as to form a variable resistance material layer including a plurality of first oxygen-rich metal oxide layers 12A-1, 12A-2, . . . , 12A-N (where N is an integer) and a plurality of first oxygen-deficient metal oxide layers 12B-1, 12B-2, . . . , 12B-N which are alternately stacked in a vertical direction.

Subsequently, a second electrode 14 and a second metal oxide layer (refer to reference numeral 22 of FIG. 1D) are formed over the resultant structure. A second implantation process for reducing the second metal oxide layer into a combination of a second oxygen-deficient metal oxide layer and a second oxygen-rich metal oxide layer is performed with having a passivation layer (not illustrate) over the second metal oxide layer.

At this time, a plurality of secondary implantations may be performed with different energies so as to form a variable resistance material layer including a plurality of second oxygen-deficient metal oxide layers 22B-N, . . . , 22B-2, 22B-1 and a plurality of second oxygen-rich metal oxide layers 22A-N, . . . , 22A-2, and 22A-1, which are alternately stacked in a vertical direction.

During the primary and the secondary implantation processes to form the first and the second oxygen-deficient metal oxide layers 12B-1 . . . 12B-N and 22B-1 . . . 22B-N, the lowermost portion may be subjected to an implantation employing the largest energy. The lesser implantation energy is applied, the higher location is obtained where the first or the second oxygen-deficient metal oxide layers 12B-1 . . . 12B-N or 22B-1 . . . 22B-N is formed.

The variable resistance material layer of the first memory cell MC1, and the variable resistance material layer of the second memory cell MC2, may be formed to be symmetrical to each other.

In accordance with the embodiment, it is possible to not only form the double layer of the oxygen-deficient metal oxide layer and the oxygen-rich metal oxide layer, but also to form the structure in which multiple oxygen-deficient metal oxide layers and multiple oxygen-rich metal oxide layers are alternately stacked, when appropriate. Furthermore, it may be possible to form memory cells stacked symmetrically to each other.

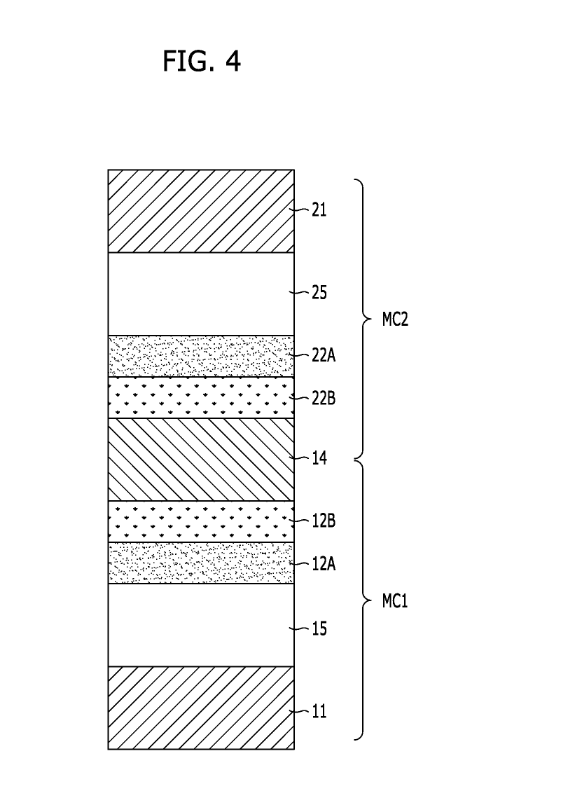

FIG. 4 is a cross-sectional view illustrating a variable resistance memory device in accordance with another embodiment. The following descriptions will be focused on differences from the above-described embodiment of FIG. 1F.

Referring to FIG. 4, the first memory cell MC1 may further include a first selecting element 15 interposed between the first electrode 11 and the first variable resistance material layer 12A and 12B, and the second memory cell MC2 may further include a second selecting element 25 interposed between the third electrode 21 and the second variable resistance material layer 22A and 22B.

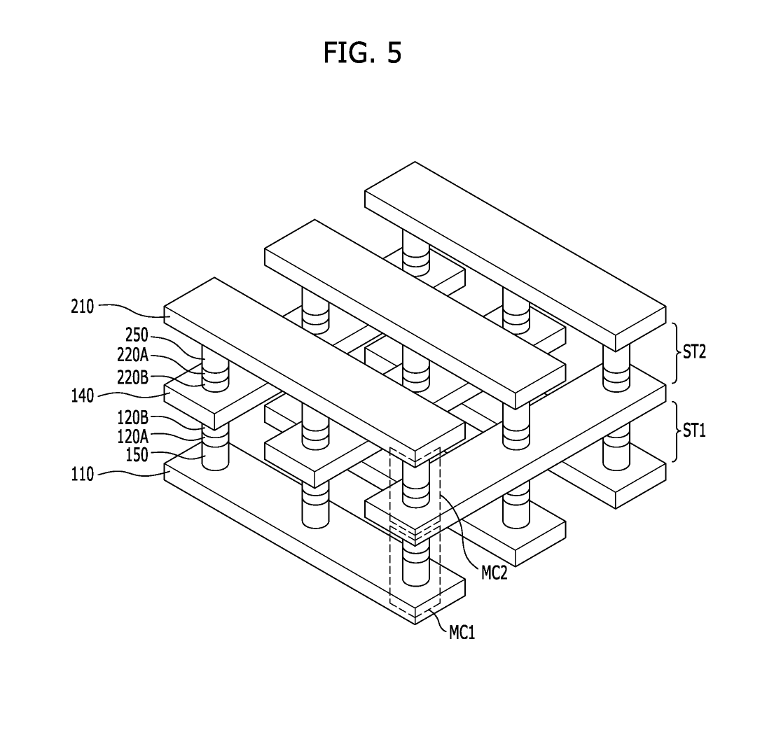

The first and the second selecting elements 15 and 25 are configured to turn on the memory cell MC1, MC2 at a predetermined current or voltage, and may include a diode, a transistor, a tunnel barrier, a metal-insulator transition (MIT) element and the like. The first and the second selecting elements 15 and 25 may serve to prevent current leakage between memory cells in a cross-point structure which will be described below with reference to FIG. 5. Each of the first and second selecting elements 15 and 25 may be arranged between a variable resistance material layer and an electrode. For example, the first and second selecting elements 15 and 25, may be interposed between the second electrode 14 and the first variable resistance material layer 12A and 12B and between the second electrode 14 and the second variable resistance material layer 22A and 22B, respectively.

Like the variable resistance material layer, the first and second selecting elements 15 and 25 may be disposed in a symmetrical manner to each other, with respect the second electrode 14 interposed therebetween.

FIG. 5 is a perspective view of a variable resistance memory device in accordance with another embodiment. In particular, FIG. 5 illustrates a variable resistance memory device having a cross-point structure.

Referring to FIG. 5, the variable resistance memory device includes a first stack ST1 and a second stack ST2. The first stack ST1 includes a plurality of first conductive lines 110, a plurality of second conductive lines 140, and a stacked structure of a first selecting element 150 and a first variable resistance material layer 120A and 120B. The plurality of first conductive lines 110 are extended in a first direction and arranged in parallel to each other. The plurality of second conductive lines 140 are extended in a second direction crossing the first direction and arranged in parallel to each other. The stacked structure of the first selecting element 150 and the first variable resistance material layer 120A and 120B is interposed between the first and second conductive lines 110 and 140 at intersections of the first and second conductive lines 110 and 140. The first stack ST1 has a cross-point structure, a unit memory cell (refer to MC1) is disposed at each of the intersections of the first and second conductive lines 110 and 140, and the first and second conductive lines 110 and 140 may function as electrodes of the memory cell. In this embodiment, the unit memory cell MC1 is substantially identical to the unit memory cell shown in FIG. 4. However, the embodiments are not limited thereto, and the unit memory cell shown at least in FIG. 1F or 3 may be used.

The second stack ST2 is arranged over the first stack ST1. The second stack ST2 includes the second conductive lines 140, a plurality of third conductive lines 210, and a stacked structure of a second variable resistance material layer 220B and 220A and a second selecting element 250. The plurality of third conductive lines 210 are extended in the first direction crossing the second conductive lines 140 and arranged in parallel to each other. The stacked structure of the variable resistance material layer 220B and 220A and the second selecting element 250 is interposed between the second and third conductive lines 140 and 210 at each of the intersections of the second and third conductive lines 140 and 210. Similarly, a unit memory cell is arranged at each of intersections between the second and third conductive lines 140 and 210 (referred to as MC2), and the second conductive line 140 and the third conductive line 210 may function as electrodes of the memory cell. The second conductive line 140 may be shared by the first and the second stacks ST1 and ST2.

In accordance with the embodiment, a two-stack cross-point structure may be implemented. A combination of the first selecting element 150 and the first variable resistance material layer 120A and 120B of the first stack ST1 and a combination of the second selecting element 250 and the second variable resistance material layer 220A and 220B of the second stack, may be arranged to be symmetrical to each other, with respect to the second conductive line 140 interposed between the two combinations.

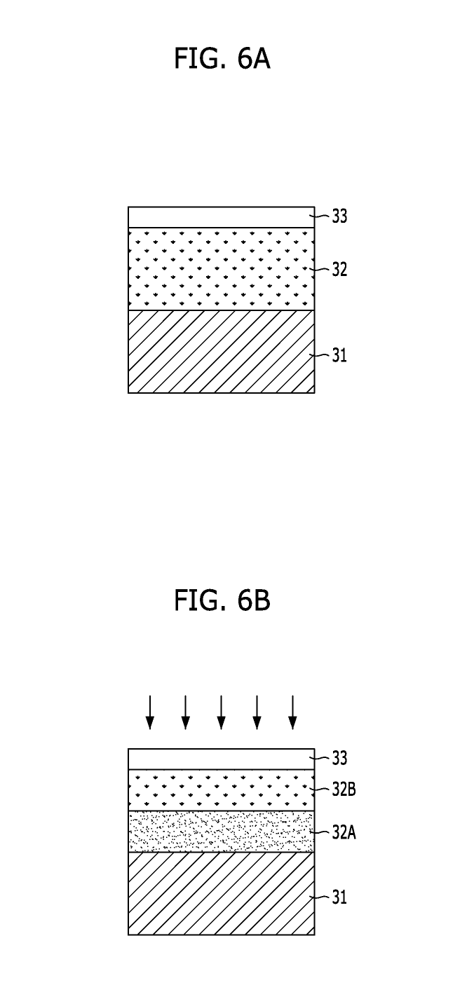

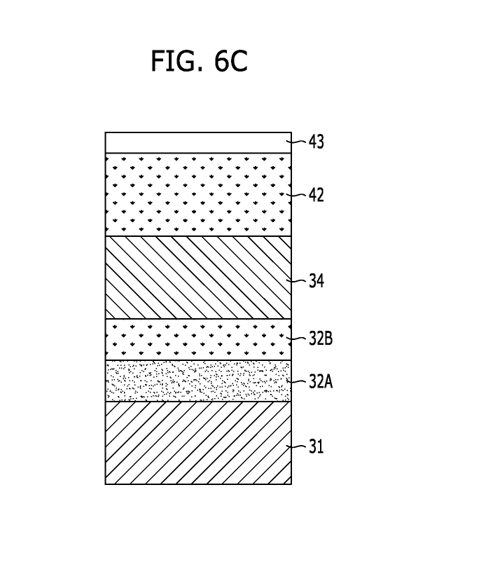

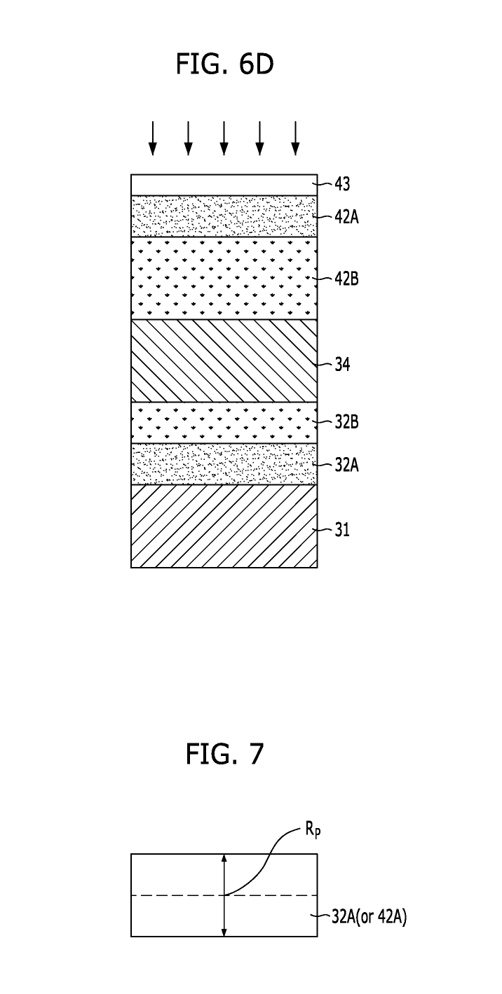

In the above-described embodiments, it has been described that a portion of the oxygen-rich metal oxide layer is reduced to the oxygen-deficient metal oxide layer to form the variable resistance material layer. On the other hand, the oxygen-deficient metal oxide layer may be first formed, and partially oxidized to form the oxygen-rich metal oxide layer. In this case, an implantation process may be used to form the oxygen-rich metal oxide layer at a desired position. Hereafter, referring to FIGS. 6A to 7, an example of such an embodiment will be described in more detail.

FIGS. 6A to 6D are cross-sectional views illustrating a variable resistance memory device and a method for fabricating the same in accordance with an embodiment. The detailed descriptions on substantially the same components as those illustrated in FIGS. 1A to 1F are omitted herein.

Referring to FIG. 6A, a first electrode 31 is formed over a substrate (not illustrated) having a predetermined lower structure.

Then, a first metal oxide layer 32 is formed over the first electrode 31. The first metal oxide layer 32 may include Ti oxide, Ta oxide, Fe oxide, W oxide, Hf oxide, Nb oxide, Zr oxide, a combination thereof, and the like, for example. Furthermore, the first metal oxide layer 32 may include oxygen-deficient metal oxide having a relatively low oxygen content compared with an oxygen-rich metal oxide layer. For example, the first metal oxide layer may include a metal oxide layer such as TiO₂ (0≦x≦2) or Ta₂O₅ (0≦x≦2.5) which contains oxygen-per-metal at a lower ratio than a stoichiometric ratio.

Then, a first passivation layer 33 is formed over the first metal oxide layer 32.

Referring to FIG. 6B, an element capable of partially oxidizing the first metal oxide layer 32 (for example oxygen) is primarily implanted into the first metal oxide layer 32 (refer to arrows), and a heat treatment is performed to oxidize a portion of the first metal oxide layer 32. The oxidized portion of the first metal oxide layer 32 has a higher oxygen-per-metal ratio than the first metal oxide layer 32. Thus, hereafter, the oxidized portion of the first metal oxide layer 32 is referred to as a first oxygen-rich metal oxide layer 32A. The remaining portion of the first metal oxide layer 32 which is not oxidized, is referred to as a first oxygen-deficient metal oxide layer 32B. The first oxygen-rich metal oxide layer 32A may include a layer such as TiO₂ or Ta₂O₅, which satisfies a stoichiometric ratio.

In this embodiment, as the primary implantation is performed with relatively high implantation energy, a bottom portion of the first metal oxide layer 32 is oxidized to form the first oxygen-rich metal oxide layer 32A. However, embodiments are not limited thereto. Depending on the energy level employed during the implant process, the oxygen-rich metal oxide layer may be formed at a desired location or depth. Referring to FIG. 6C, the first passivation layer 13 is removed, and a second electrode 34, a second metal oxide layer 42, and a passivation layer 43 are formed over the resultant structure. The second metal oxide layer 42 may be formed of the same material as the first metal oxide layer 32 and formed to the same thickness as the first metal oxide layer 32. Accordingly, the second metal oxide layer 42 may include an oxygen-deficient metal oxide layer.

Referring to FIG. 6D, an element capable of oxidizing the second metal oxide layer 42 (for example oxygen) is implanted into the second metal oxide layer 42 (see arrows), and a heat treatment is performed to oxidize a portion of the second metal oxide layer 42, thereby forming a second oxygen-rich metal oxide layer 42A. The remaining portion of the second metal oxide layer 42, which is not oxidized, is referred to as a second oxygen-deficient metal oxide layer 42B.

In this embodiment, as the secondary implantation is performed at lower energy level than that employed for the primary implantation, the top part of the second metal oxide layer 42 may be oxidized to form the second oxygen-rich metal oxide layer 42A. The secondary implantation may be performed under the same conditions as the primary implantation, except for the implantation energy.

Subsequently the second passivation layer 43 is removed and a third electrode is then formed over the resultant structure, thereby fabricating substantially the same unit cell as shown in FIG. 1F. As such, even when the oxidization is used, it is possible to implement a device where the structure in which the oxygen-rich metal oxide layers and the oxygen-deficient metal oxide layers are alternately stacked as illustrated in FIG. 3. The structure may further include the selecting elements shown as illustrated in FIG. 4, and forms the cross-point structure shown in FIG. 5. However, the oxygen-rich metal oxide layers may have different oxygen-per-metal ratios from each other. This will be described below in more detail with reference to FIG. 7.

FIG. 7 is a cross-sectional view for explaining the oxygen concentration profile in the oxygen-rich metal oxide layer of FIGS. 6A to 6D.

As described above, the first oxygen-rich metal oxide layer 32A may be formed by the implantation and the heat treatment. A range in which the element is projected in a vertical direction from the surface of the first metal oxide layer 32 during the implantation is referred to as a projected range (Rp). During the heat treatment after the implant, the element is diffused in a vertical direction (along an arrow) from the Rp (the dotted line in FIG. 7). As a result, the first oxygen-rich metal oxide layer 32A is formed.

Therefore, referring to FIG. 7, the first oxygen-rich metal oxide layer 32A may have an oxygen distribution profile that the oxygen concentration is the highest at the Rp and becomes lower as a distance from the Rp increases along the vertical direction (the arrow direction).

Similarly, in the second oxygen-rich metal oxide layer 42A, the oxygen concentration may be the highest at the Rp and becomes lower as a distance from the Rp increases along the vertical direction (the arrow direction).

In accordance with the embodiments it is possible to implement a multi-stack structure which may have an excellent switching characteristic through process improvement and symmetrical configuration.

Although various embodiments have been described for illustrative purposes, it will be apparent to those skilled in the art that various changes and modifications may be made without departing from the spirit and scope of the invention as defined in the following claims.

What is claimed is:

1. A method for fabricating a variable resistance memory device, comprising:
forming a first metal oxide layer over a first electrode;
performing a first implantation process using a first element to a first depth of the first metal oxide layer so as to reduce at least a portion of the first metal oxide layer and form a first oxygen-deficient metal oxide layer;
forming a second electrode over the first metal oxide layer;
forming a second metal oxide layer over the second electrode;
performing a second implantation process using a second element to a second depth of the second metal oxide layer so as to reduce at least a portion of the second metal oxide layer and form a second oxygen-deficient metal oxide layer; and
forming a third electrode over the second metal oxide layer.

2. The method of claim 1, wherein the first implantation process is performed using a first implantation energy different from a second implantation energy of the second implantation process.

3. The method of claim 1, wherein the first oxygen-deficient metal oxide layer and the second oxygen-deficient metal oxide layer are arranged symmetrically to each other, with respect to the second electrode interposed therebetween.

4. The method of claim 1, wherein each of the first and the second metal oxide layers satisfies a stoichiometric ratio.

5. The method of claim 1, wherein the first and the second implantation processes are performed with first and second passivation layers formed over the first and the second metal oxide layers, respectively.

6. The method of claim 5, wherein the first and the second passivation layers include an insulator, and are removed after the first and the second implantation processes are performed, respectively.

7. The method of claim 1, wherein each of the first and the second elements comprise hydrogen, silicon, aluminum, or a combination thereof.

8. The method of claim 1, wherein:
the first implantation is performed a plurality of times to a plurality of first depths different from each other so as to form a plurality of first oxygen-deficient metal oxide layers at different positions in the first metal oxide layer, and
the second implantation is performed a plurality of times to a plurality of second depths different from each other so as to form a plurality of second oxygen-deficient metal oxide layers at different positions in the second metal oxide layer.

9. The method of claim 8, wherein the plurality of first oxygen-deficient metal oxide layers and the plurality of second oxygen-deficient metal oxide layers are formed symmetrical to each other with respect to the second electrode interposed therebetween.

10. A method for fabricating a variable resistance memory device, comprising:
forming a first metal oxide layer over a first electrode;
performing a first implantation process using a first element to a first depth of the first metal oxide layer so as to oxidize at least a portion of the first metal oxide layer and form a first oxygen-rich metal oxide layer;
forming a second electrode over the first metal oxide layer;
performing a second implantation process using a second element to a second depth of the second metal oxide layer so as to oxidize at least a portion of the second metal oxide layer and form a second oxygen-rich metal oxide layer; and
forming a third electrode over the second metal oxide layer.

11. The method of claim 10, wherein the first implantation is performed with a first implantation energy different from a second implantation energy of the second implantation process.

12. The method of claim 10, wherein the first oxygen-rich metal oxide layer and the second oxygen-rich metal oxide layer are formed symmetrical to each other with respect to the second electrode interposed therebetween.

13. The method of claim 10, wherein each of the first and the second oxygen-rich metal oxide layers satisfies a stoichiometric ratio.

14. The method of claim 10, wherein the first and the second implantation processes are performed with first and second passivation layers formed over the first and the second metal oxide layers, respectively.

15. The method of claim 14, wherein the first and the second passivation layers include insulator, and are removed after the first and the second implantation are performed, respectively.

16. The method of claim 10, wherein the first and the second elements comprise oxygen.

17. The method of claim 10, wherein:
the first implantation is performed a plurality of times to a plurality of first depths different from each other so as to form a plurality of first oxygen-rich metal oxide layers at different positions in the first metal oxide layer, and
the second implantation is performed a plurality of times to a plurality of second depths different from each other so as to form a plurality of second oxygen-rich metal oxide layers at different positions in the second metal oxide layer.

18. The method of claim 17, wherein the plurality of first oxygen-rich metal oxide layers and the plurality of second oxygen-rich metal oxide layers are formed symmetrical to each other with respect to the second electrode interposed therebetween.

19. A variable resistance memory device comprising:
a first electrode;
a first variable resistance material layer formed over the first electrode and comprising a stack of a first oxygen-deficient metal oxide layer and a first oxygen-rich metal oxide layer;
a second electrode over the first variable resistance material layer;
a second variable resistance material layer formed over the second electrode and comprising a stack of a second oxygen-deficient metal oxide layer and a second oxygen-rich metal oxide layer; and
a third electrode over the second variable resistance material layer,
wherein the first and the second variable resistance material layers in a symmetrical configuration with respect to the second electrode interposed therebetween, and
wherein, in each of the first and the second oxygen-deficient metal oxide layers, an oxygen-per-metal ratio is the lowest at a given level and increases as a distance from the given level increases in a thickness direction.

20. A variable resistance memory device comprising:
a first electrode;
a first variable resistance material layer formed over the first electrode and comprising a stack of a first oxygen-deficient metal oxide layer and a first oxygen-rich metal oxide layer;
a second electrode over the first variable resistance material layer;
a second variable resistance material layer formed over the second electrode and comprising a stack of a second oxygen-deficient metal oxide layer and a second oxygen-rich metal oxide layer; and
a third electrode over the second variable resistance material layer,
wherein the first and second variable resistance material layers are in a symmetrical configuration with respect to the second electrode interposed therebetween, and
wherein, in each of the first and the second oxygen-rich metal oxide layers, an oxygen-per-metal ratio is the highest at a given level and decreases as a distance from the given level increases in a thickness direction.

21. A method for fabricating a variable resistance memory device, comprising:
providing a first metal oxide layer over a first electrode, wherein the first metal oxide layer has a first oxygen-per-metal ratio;
performing a first implantation process to the first metal oxide layer to modify a portion of the first metal oxide layer into a first modified metal oxide layer, wherein the first modified metal oxide layer has a second oxygen-per-metal ratio different from the first oxygen-per-metal ratio;
forming a second electrode over a stack of the first metal oxide layer and the first modified metal oxide layer;
forming a second metal oxide layer over the second electrode, wherein the second metal oxide layer has a third oxygen-per-metal ratio;
performing a second implantation process to the second metal oxide layer to modify a portion of the second metal oxide layer into a second modified metal oxide layer, wherein the second modified metal oxide layer has a fourth oxygen-per-metal ratio different from the third oxygen-per-metal ratio.

22. The method of claim 21,
wherein the first and the third oxygen-per-metal ratios satisfy stoichiometric ratio, respectively, and
wherein the second and the fourth oxygen-per-metal ratios are lower than the first and the third oxygen-per-metal ratio, respectively.

23. The method of claim 21,
wherein the second and the fourth oxygen-per-metal ratios satisfy stoichiometric ratio, respectively, and
wherein the first and the third oxygen-per-metal ratios are lower than the second and the fourth oxygen-per-metal ratio, respectively.

24. The method of claim 21,
wherein each of the first and the second metal oxide layer is formed by a deposition process.

25. The method of claim 21,
wherein when each the first and the second metal oxide layers has a substantially uniform oxygen-per-metal ratio profile along a thickness direction, each of the first and the second modified metal oxide layers has a differential oxygen-per-metal ratio profile along a thickness direction along the thickness direction.
wherein when each the first and the second metal oxide layers has a differential oxygen-per-metal ratio profile along the thickness direction, each of the first and the second modified metal oxide layers has a substantially uniform oxygen-per-metal ratio profile along the thickness direction.

26. A variable resistance memory device comprising:
a first electrode;
a first variable resistance material layer formed over the first electrode and comprising a stack of a first oxygen-deficient metal oxide layer and a first oxygen-rich metal oxide layer;
a second electrode over the first variable resistance material layer;
a second variable resistance material layer formed over the second electrode and comprising a stack of a second oxygen-deficient metal oxide layer and a second oxygen-rich metal oxide layer; and
a third electrode over the second variable resistance material layer,
wherein when each the first and the second oxygen-deficient metal oxide layers is configured to have a differential oxygen-per-metal ratio profile along a thickness direction, each of the first and the second oxygen-rich metal oxide layers is configured to have a substantially uniform oxygen-per-metal ratio profile along the thickness direction, and
wherein when each the first and the second oxygen-deficient metal oxide layers is configured to have a substantially uniform oxygen-per-metal ratio profile along the thickness direction, each of the first and the second oxygen-rich metal oxide layers is configured to have a differential oxygen-per-metal ratio profile along the thickness direction.
